(19) United States
(12) Patent Application Publication
(10) Pub. No.: US 2024/0170924 A1
(43) Pub. Date: May 23, 2024

(54) OPTICAL MODULATOR

(71) Applicant: Nippon Telegraph and Telephone Corporation, Tokyo (JP)

(72) Inventors: Manabu Mitsuhara, Tokyo (JP); Wataru Kobayashi, Tokyo (JP)

(21) Appl. No.: 18/551,235

(22) PCT Filed: Apr. 5, 2021
(86) PCT No.: PCT/JP2021/014441

§ 371 Date: Sep. 19, 2023

(51) Int. Cl. H01S 5/343; H01S 5/026

(52) U.S. Cl. CPC H01S 5/34373; H01S 5/0265; H01S 5/3434

(57) ABSTRACT

An optical modulator is formed on a substrate constituted of InP, and an active layer is formed on the substrate via a lower InP layer constituted of InP. The active layer has a multiple quantum well structure including a well layer constituted of a group III-V compound semiconductor including In, As, and P as constituent elements and a barrier layer constituted of a group III-V compound semiconductor including In, Ga, P, and Sb as constituent elements.

### CROSS-REFERENCE TO RELATED APPLICATIONS

This application is a national phase entry of PCT Application No. PCT/JP2021/014441, filed on Apr. 5, 2021, which application is hereby incorporated herein by reference.

### TECHNICAL FIELD

The present invention relates to an optical modulator.

### BACKGROUND

With the recent progress of the Internet of Things (IOT), cloud computing, and the like, the amount of information communication is rapidly increasing. In order to cope with this rapidly increasing communication amount, as a matter of course, in a case where transmission distance is long, electric communication using conventional metallic cables is being replaced with optical communication using optical fibers even for access networks connected to homes and small office home offices (SOHO) and the like with short transmission distance.

In the optical communication using optical fibers, intensity, a phase, and the like of light propagating through the optical fiber are modulated on the incident side, so that an optical signal is generated by switching an on state and an off state of light on the emission side, and the generated optical signal is transmitted through the optical fiber. When the communication speed is increased in the optical fiber communication, it is necessary to switch the on state and the off state of the light at high speed.

A semiconductor laser is used as a light source in optical fiber communication. In order to cause laser oscillation of a semiconductor laser, it is necessary to inject a large number of carriers (electrons and holes). However, in the method of directly controlling the carrier density injected into the semiconductor laser, it is difficult to switch between an on state (laser oscillation state) and an off state (laser non-oscillation state) at a speed exceeding 20 Gbps. Thus, in order to switch on and off of light at high speed, it is common to keep the semiconductor laser in an oscillation state at all times, and perform switching of on and off by another optical element (optical modulator).

The optical modulator using a semiconductor can be manufactured by being integrated on the same semiconductor substrate as the laser, and thus it is useful for reducing the manufacturing cost of the entire light source and simplifying the mounting. Thus, the optical modulator using a semiconductor is often integrated with a laser, and research and development of a light source in which the optical modulator and the laser are integrated are energetically advanced.

In the optical modulator using a semiconductor, a quantum well structure is used. The reason for using the quantum well structure is that light absorption by excitons (electron-hole pairs bound by Coulomb attraction) is larger when using the quantum well structure than when using a bulk structure, a trail to a long wavelength side can be reduced when an external electric field is applied for the excitons, and consequently, it is advantageous in terms of increasing an on/off ratio (hereinafter referred to as an extinction ratio) of light.

FIG. 10 is a diagram schematically illustrating an operation principle of an optical modulator using this quantum well structure. As illustrated in (a) of FIG. 10, band gap energy of a well layer of the quantum well structure in a state where no external electric field is applied is denoted by E₁. When E, is greater than energy (E_{IN}) of incident light, the incident light passes without being absorbed by the quantum well structure.

On the other hand, as illustrated in (b) of FIG. 10, when the external electric field is applied, band gap energy E₂ of the well layer becomes smaller than E₁. This phenomenon is known as quantum confined Stark effect (QCSE), and the energy difference (E₁−E₂) between E₁ and E₂ is known to be approximated by “m*×F²×L_{w}⁴ . . . (1)”. Here, m* is an effective mass of the well layer, F is intensity of the external electric field, and L_{w} is thickness of the well layer. As can be seen from Expression (1), by increasing the external electric field, the band gap energy E₂ of the well layer becomes smaller than the energy E_{IN} of the incident light, and as a result, light absorption occurs.

In this case, a band gap (E₁ without application of electric field or E₂ with application of electric field) of the quantum well structure needs to satisfy the relationship of E₁>E_{IN}>E₂ with respect to the energy (E_{IN}) of the incident light. If E₁ is too close to E_{IN}, the rate at which the incident light is absorbed by the quantum well structure increases even in a state where no electric field is applied. On the other hand, when E₁ is excessively separated from E_{IN}, large electric field intensity needs to be added to satisfy E_{IN}>E₂, and the power consumption of the light source increases.

In general, the wavelength (hereinafter referred to as a band gap wavelength) corresponding to the band gap E₁ of the quantum well structure used in the optical modulator is set to a short wavelength side of about 40 nm to 70 nm with respect to the wavelength of the incident light. By applying an electric field to the quantum well structure, the absorption edge is shifted to a long wavelength side, whereby light absorption occurs, and electrons and holes generated at this time move from the inside of the quantum well structure to a low potential side and a high potential side, respectively. The above is the basic operation principle of the optical modulator using the quantum well structure.

Next, a structure effective for improving characteristics of the optical modulator using this quantum well structure will be described. First, a structure necessary for increasing the extinction ratio will be described.

In the quantum well structure, when an electric field is applied, wave functions of electrons and holes are shifted in opposite directions in the well layer. In order to rapidly change the absorption coefficient in the vicinity of the absorption edge when the electric field is applied, it is necessary to suppress exudation of a wave function in the well layer to a barrier layer. The exudation of a wave function is larger for electrons than for holes. In order to suppress the exudation of the wave function in the well layer to the barrier layer, it is effective to increase a band discontinuity of a conduction band in the quantum well.

Further, as described above, the amount of decrease in the band gap when a voltage is applied is proportional to the square of the electric field intensity and the fourth power of the thickness of the well layer. Thus, in order to efficiently shift the absorption edge to the low energy side with small electric field intensity, it is effective to increase the film thickness of the well layer in the quantum well structure.

Since increasing the thickness of the well layer leads to an increase in light absorption, it is also effective in increasing the extinction ratio. From the above, in order to increase the extinction ratio, it is effective to increase the band discontinuity in the conduction band and to increase the thickness of the well layer in the quantum well structure.

Next, a structure for causing the optical modulator to operate at high speed will be described. As described with reference to (b) of FIG. 10, the electrons generated by light absorption move from the inside of the quantum well structure to the low potential side by the external electric field. On the other hand, the holes generated by light absorption move from the inside of the quantum well structure to the high potential side by the external electric field. In order to cause the optical modulator to operate at high speed, it is necessary to cause the electrons and the holes to move from the quantum well structure at high speed. Since electrons have a small effective mass, when only the electrons are considered, it is easy to cause the electrons to move from the inside of the quantum well structure at a speed of about several tens of GHz.

On the other hand, holes have a large effective mass, and it is more difficult to cause the holes to move from the inside of the quantum well structure at high speed than electrons. When holes remain in the quantum well structure without moving, movement of electrons is suppressed by a space charge effect. Furthermore, when the movement of holes and electrons is suppressed, the refractive index of the entire optical modulator varies with time during high-speed modulation, and as a result, the optical pulse waveform after optical fiber transmission is deteriorated, which causes chirping. In the quantum well structure, the smaller the band discontinuity of the valence band, the easier the movement of holes from the well layer to the barrier layer. From the above, in order to cause the optical modulator to operate at high speed, it is effective to reduce the band discontinuity in the valence band.

InGaAsP has a band gap wavelength suitable for optical fiber communication, and thus it is widely used for a laser, a light receiver, and the like. A problem of an optical modulator using InGaAsP for the well layer and the barrier layer will be described. As described above, in order to increase the extinction ratio in the optical modulator, it is effective to use the quantum well structure that has a large band discontinuity in the conduction band. For this purpose, it is necessary to increase the band gap of the barrier layer. The band gap can be changed by adjusting the composition ratio of InGaAsP.

FIG. 11 is a diagram schematically illustrating a change in band arrangement when the band gap of the barrier layer is changed from E_{g}(B1) to E_{g}(B2) without changing the well layer in the quantum well structure using InGaAsP for the well layer and the barrier layer. By increasing the band gap of the barrier layer, the band discontinuity in the conduction band is increased from ΔE_{c}(B1) to ΔE_{c}(B2). Thus, it is possible to suppress the exudation of the wave function in the well layer and leakage of the electrons to the barrier layer. However, by increasing the band gap of the barrier layer, the band discontinuity in the valence band also increases from ΔEᵥ(B1) to ΔEᵥ(B2).

The ratio of band discontinuity between the conduction band and the valence band (band discontinuity of conduction band/band discontinuity of valence band) is mainly determined by the material constituting the quantum well structure. In the quantum well structure using InGaAsP, the above-described ratio is generally set to about 4/6. Thus, in the quantum well structure in which InGaAsP is used for the well layer and the barrier layer, the band discontinuity of the valence band changes more greatly than the conduction band by increasing the band gap of the barrier layer. Consequently, it becomes difficult to cause the holes to move from the well layer at high speed, and it becomes difficult to cause the optical modulator to operate at high speed. That is, in the optical modulator using InGaAsP for the well layer and the barrier layer, it is difficult to achieve both the large extinction ratio and high-speed operation.

In order to achieve both the large extinction ratio and the high-speed operation in the optical modulator using the semiconductor quantum well structure, the “band discontinuity of conduction band/band discontinuity of valence band” may be increased. In the quantum well structure using InGaAlAs for the well layer and the barrier layer, the “band discontinuity of conduction band/band discontinuity of valence band” is considered to be about 7/3.

Thus, in the quantum well structure using InGaAlAs for the well layer and the barrier layer, even if the band gap of the barrier layer is increased, an increase in band discontinuity of the valence band can be suppressed as compared with a case of using InGaAsP. Actually, in research of the optical modulator using the quantum well structure, InGaAlAs is often used for the well layer and the barrier layer of the quantum well structure rather than InGaAsP.

On the other hand, in order to bring the optical modulator into practical use, it is important to obtain stable device characteristics over a long period of time, that is, what is called long-term stability. However, since a material containing Al is easily affected by oxidation, it is difficult to secure long-term stability in a device using the material. That is, when InGaAlAs is used for the well layer and the barrier layer of the quantum well structure, the problem of band discontinuity in the optical modulator can be avoided as described above, but there is a problem that it is difficult to secure long-term reliability.

### CITATION LIST

### Non Patent Literature

Non Patent Literature 1: H. Oohashi et al., “1.3 μm InAsP compressively strained multiple-quantum-well lasers for hightemperature operation”, Journal of Applied Physics, vol. 77, no. 8, pp. 4119-4121, 1995.

Non Patent Literature 2: H. Sugiura et al., “Metalorganic molecular beam epitaxy of strain-compensated InAsP/InGaAsP multiquantum-well lasers”, Journal of Applied Physics, vol. 79, no. 3, pp. 1233-1237, 1996.

### SUMMARY

### Technical Problem

As an effective method for avoiding both the problem related to the band discontinuity of the optical modulator using the quantum well structure described above and the problem of long-term reliability, it is conceivable to use a material having a “band discontinuity of conduction band/band discontinuity of valence band” larger than that of the quantum well structure using InGaAsP and not containing Al for the well layer and the barrier layer of the quantum well structure.

As a quantum well structure having a large “band discontinuity of conduction band/band discontinuity of valence band” using a material system not containing Al in an active layer used for the semiconductor laser, a structure using InAsP for the well layer and InGaAsP for the barrier layer is known (see, for example, Non Patent Literature 1). Furthermore, it is known that good long-term reliability is obtained in a semiconductor laser using a quantum well structure with InAsP for the well layer (see, for example, Non Patent Literature 2).

The band gap wavelength in the InAsP well layer can be made longer as the molar composition ratio of As in InAsP is increased. In this case, a large compressive strain is applied to InAsP, but when a tensile strain is applied to the barrier layer to form the quantum well structure into a strain compensation structure, deterioration of crystallinity caused by the compressive strain of the InAsP well layer is not observed, and a laser oscillating at a wavelength of around 1.3 μm and having good device characteristics can be produced (see, for example, Non Patent Literature 1 and Non Patent Literature 2).

FIG. 12 is a diagram illustrating a change in a band gap wavelength depending on the thickness of the well layer in the quantum well structure with InAsP for the well layer and InGaAsP for the barrier layer. In FIG. 12, the strain amount of the InAsP well layer is changed from +1.1% to +1.6%. Further, the upper limit of the thickness is 12 nm at which a clear quantum size effect can be obtained and the well layer can easily function as a quantum well. The InGaAsP barrier layer has a band gap wavelength of 1.0 μm, and a strain amount of −0.6% is added so as to form a strain compensation structure in combination with the InAsP well layer. In optical fiber communication, wavelength light around 1.3 μm is widely used. More specifically, in the O band of Coarse Wavelength Division Multiplexing (CWDM), wavelength light of 1.26 μm to 1.36 μm is used.

As described above, in the optical modulator using the quantum well structure, the band gap wavelength is generally set to a shorter wavelength side than the wavelength of incident light by about 40 nm to 70 nm. As described above, in the optical modulator corresponding to the wavelength light around 1.3 μm, it is necessary to set the band gap wavelength of the active layer within the wavelength range of 1.19 μm to 1.32 μm.

As can be seen from FIG. 12, in the quantum well structure using InAsP for the well layer, if the strain amount of the InAsP well layer is set in the range of +1.1% to +1.6%, this wavelength range can be covered.

As described above, in order to cause the optical modulator to operate with small electric field intensity and further increase the extinction ratio, it is effective to use a quantum well structure having a large well layer thickness. In the optical modulator, the quantum well structure having the well layer with a thickness of 6 nm or more is generally used.

FIG. 13 is a characteristic diagram illustrating results of changing the band gap wavelength when the strain amount to be applied to the InGaAsP barrier layer is changed from −0.6% to −0.4% and −1.0%, the thickness of the InAsP well layer is set to 8 nm, and the strain amount is changed. (a) of FIG. 13 illustrates a case where the strain amount is −0.6%, and (b) of FIG. 13 illustrates a case where the strain amount is −1.0%. As can be seen from FIG. 13, even in a case where the thickness of the InAsP well layer is set to 6 nm or more, it is possible to obtain a band gap wavelength required for the optical modulator corresponding to the wavelength light around 1.3 μm described above.

However, when the thickness of the InAsP well layer is increased, a new problem arises in applying the quantum well structure to an optical modulator. This problem will be described below.

When a quantum well structure having a well layer constituted of InAsP is applied to a laser oscillating around a wavelength of 1.3 μm, the thickness of the InAsP well layer is often set to be smaller than 6 nm. When the thickness of the well layer is small, quantum levels of the conduction band and the valence band are located away from a band edge (the bottom of the conduction band and the top of the valence band when there is no quantum size effect) due to the quantum size effect.

(a) of FIG. 14 schematically illustrates this situation. When the thickness of the well layer is small, the band discontinuity of the conduction band is small, but the band discontinuity of the valence band is also small. In a quantum well laser using InAsP for the well layer and InGaAsP for the barrier layer, as compared with a quantum well laser using InGaAsP for the well layer, a thickness of the well layer is set within a range in which the band discontinuity of the conduction band is not so small, and moreover, since the band discontinuity of the valence band is also small, holes are relatively uniformly injected even when a quantum well structure having 10 cycles or 15 cycles is used for a laser (see, for example, Non Patent Literature 1 and Non Patent Literature 2).

On the other hand, when the thickness of the well layer is large, the quantum levels of the conduction band and the valence band are located near the band edge as illustrated in (b) of FIG. 14. In this case, the band discontinuity of the valence band increases. Consequently, when a quantum well structure having a large well layer thickness is applied to the optical modulator, it becomes difficult to cause the holes to move from the well layer at high speed, and it becomes difficult to cause the optical modulator to operate at high speed.

As described above, the quantum well structure using the InAsP well layer is useful in a case of being applied to the optical modulator in which the thickness of the well layer is smaller than 6 nm, but there is a problem that it is not easy to cause the optical modulator to operate at high speed in a case of being applied to the optical modulator in which the thickness of the well layer is equal to or more than 6 nm.

Embodiments of the present invention have been made to solve the problems as described above, and an object thereof is to apply a quantum well structure using a well layer with InAsP to an optical modulator having a well layer thickness of 6 nm or more, so as to cause the optical modulator to operate at high speed.

### Solution to Problem

An optical modulator according to embodiments of the present invention is an optical modulator formed on a substrate constituted of InP, and includes an active layer having a multiple quantum well structure including a well layer constituted of a group III-V compound semiconductor including In, As, and P as constituent elements and a barrier layer constituted of a group III-V compound semiconductor including In, Ga, P, and Sb as constituent elements, in which a wavelength corresponding to a band gap of the multiple quantum well structure in the range of 1.19 μm to 1.32 μm.

### Advantageous Effects of embodiments of Invention

As described above, according to embodiments of the present invention, since the barrier layer is constituted of the group III-V compound semiconductor containing In, Ga, P, and Sb as constituent elements, it is possible to cause the optical modulator to operate at high speed by applying the quantum well structure using the well layer with InAsP to the optical modulator in which the thickness of the well layer is 6 nm or more.

### BRIEF DESCRIPTION OF THE DRAWINGS

FIG. 1 is a cross-sectional view illustrating a configuration of an optical modulator according to an embodiment of the present invention.

FIG. 2 is a characteristic diagram illustrating relative positions of energy at a top of a valence band at a I point with respect to InP for binary mixed crystals containing P, As, and Sb as group V elements.

FIG. 3 is a characteristic diagram illustrating a change in band discontinuity in the valence band of a quantum well structure depending on a strain amount of a well layer constituted of InAsP and a thickness of the well layer.

FIG. 4 is a characteristic diagram illustrating a change in band discontinuity in a conduction band of a multiple quantum well structure depending on the strain amount of the well layer with InAsP and the thickness of the well layer.

FIG. 5 is a characteristic diagram illustrating a change in a band gap wavelength depending on the strain amount of the well layer and the thickness of the well layer in a quantum well structure in which the well layer is constituted of InAsP and the barrier layer is constituted of InGaPSb.

FIG. 6 is a characteristic diagram illustrating a change in the band gap wavelength in an active layer of the multiple quantum well structure depending on the strain amount of the well layer.

FIG. 7 is a characteristic diagram illustrating X-ray diffraction patterns of a sample in which the number of well layers is 10 and a sample in which the number of well layers is 50.

FIG. 8 is a characteristic diagram illustrating absorption spectra for respective samples in which the number of well layers is 10, 30, and 50.

FIG. 9 is a cross-sectional view illustrating a configuration of another optical modulator according to the embodiment of the present invention.

FIG. 10 is an explanatory diagram describing an operation principle of the optical modulator using the quantum well structure.

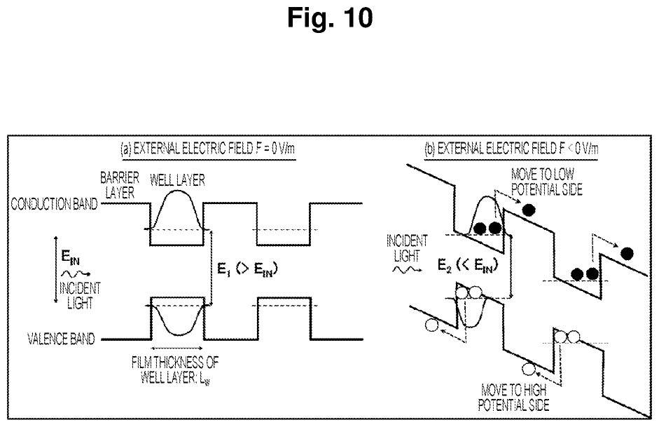

FIG. 11 is a band diagram illustrating a band arrangement of the quantum well structure using InGaAsP for the well layer and the barrier layer.

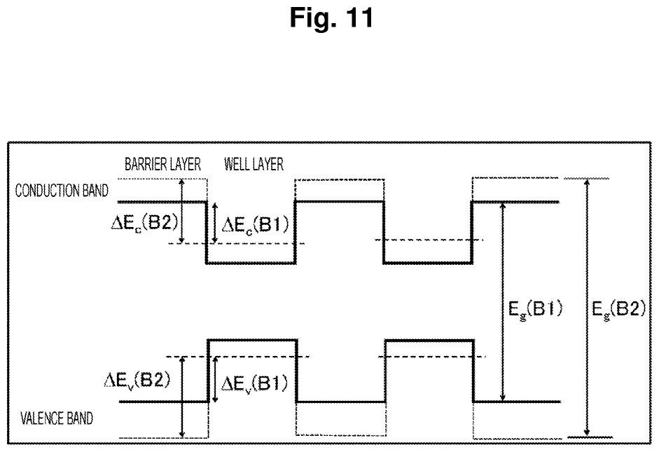

FIG. 12 is a characteristic diagram illustrating a change in the band gap wavelength depending on the thickness of the well layer of the quantum well structure with InAsP for the well layer and InGaAsP for the barrier layer.

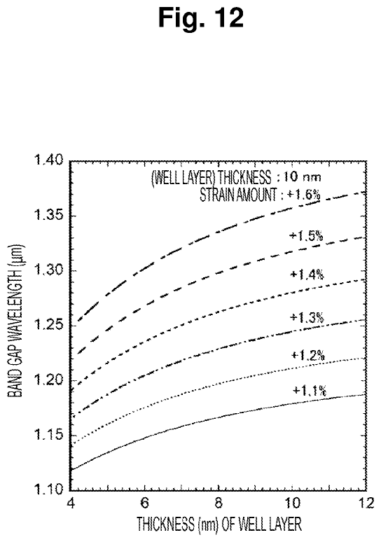

FIG. 13 is a characteristic diagram illustrating a change in the band gap wavelength when the strain amount to be applied to the InGaAsP barrier layer is changed from −0.6% to −0.4% and −1.0%, the thickness of the InAsP well layer is set to 8 nm, and the strain amount is changed.

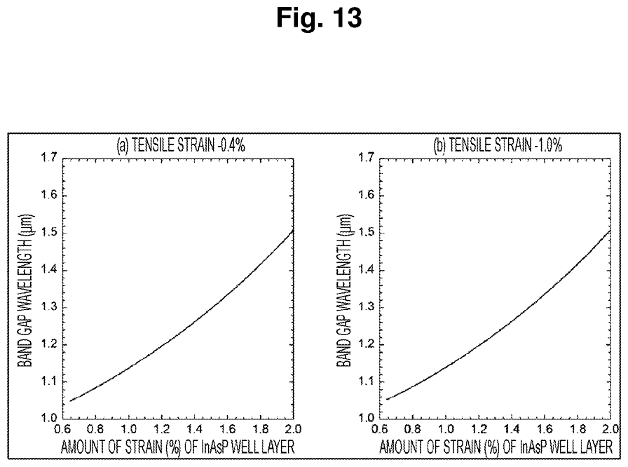

FIG. 14 is a band diagram illustrating a band arrangement of the quantum well structure using InAsP for the well layer.

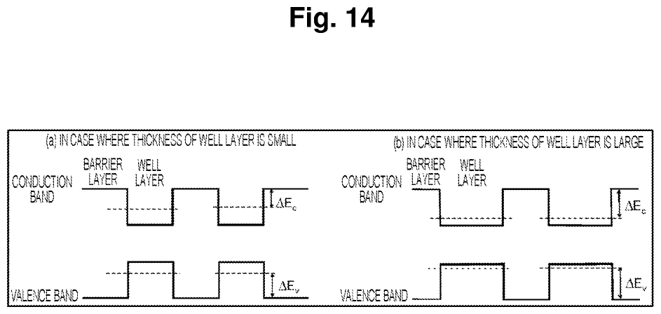

### DETAILED DESCRIPTION OF ILLUSTRATIVE EMBODIMENTS

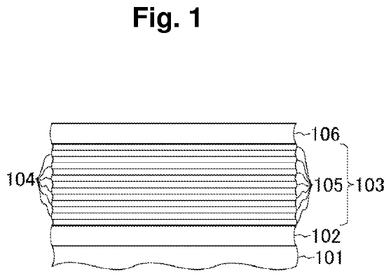

Hereinafter, an optical modulator according to an embodiment of the present invention will be described with reference to FIG. 1. This optical modulator is formed on a substrate 101 constituted of InP. This optical modulator can be integrated together with a laser on the substrate 101.

An active layer 103 is formed on the substrate 101 via a lower InP layer 102 constituted of InP. The active layer 103 has a multiple quantum well structure including a well layer 104 constituted of the group III-V compound semiconductor containing In, As, and P as constituent elements and a barrier layer 105 constituted of the group III-V compound semiconductor containing In, Ga, P, and Sb as constituent elements. Further, in this example, an upper InP layer 106 constituted of InP is formed on the active layer 103.

The well layer 104 can be constituted of InAsP, for example. The barrier layer 105 can be constituted of InGaPSb or InGaAsPSb. A molar composition ratio of Sb in the group V element of the barrier layer 105 can be larger than 0 and equal to or less than 0.2. Further, the active layer 103 has a wavelength corresponding to the band gap of the multiple quantum well structure in the range of 1.19 μm to 1.32 μm.

Further, a strain amount of the well layer 104 is in the range of +1.1% to +1.6%. Furthermore, a thickness of the well layer 104 is equal to or more than 6 nm and equal to or less than 12 nm. Note that the number of well layers 104 can be between 6 and 20.

Here, manufacturing of the optical modulator will be briefly described. Each of the layers described above can be formed by being grown by a metal organic molecular beam epitaxy method. In the crystal growth, trimethylindium (TMIn) and triethylgallium (TEGa) can be used as the group III source gas. Further, as the group V source gas, phosphine (PH₃), arsine (AsH₃), and trisdimethylaminoantimony (TDMASb) can be used.

First, undoped InP is grown on the substrate 101 constituted of n-type InP to form the lower InP layer 102 having a thickness of 0.2 μm. Subsequently, for example, by alternately growing InGaPSb and InAsP, a multiple quantum well structure including the barrier layer 105 and the well layer 104 is grown to become the active layer 103. Thereafter, undoped InP is grown to form the upper InP layer 106 having a thickness of 0.2 μm. The substrate temperature during the growth is 530° C. for the quantum well structure and 505° C.for other layers.

The well layer 104 constituted of InAsP has, for example, a strain amount with respect to InP of +1.6% and a thickness of 6.0 nm. The barrier layer 105 constituted of InGaPSb has, for example, a strain amount of −0.6% with respect to InP and a thickness of 10.5 nm. Further, for example, the Sb molar composition ratio of the barrier layer 105 is 0.03, and the band gap wavelength of the barrier layer 105 is 1.0 μm.

Next, in the optical modulator according to the embodiment, an increase in band discontinuity of the valence band is suppressed even when the thickness of the well layer is increased.

As described above, the magnitude of band discontinuity between the conduction band and the valence band in the quantum well structure is determined by materials used for the well layer and the barrier layer and the thickness of the well layer. Note that the thickness of the barrier layer used in the optical modulator is designed so that wave functions between well layers do not overlap. Thus, basically, the band discontinuity is not affected by the thickness of the barrier layer.

Regarding a binary mixed crystal containing Ga and In as group III elements, it is known that energy positions at the top of the valence band is substantially the same position if the contained group V elements are the same (see, for example, Reference Literature 1).

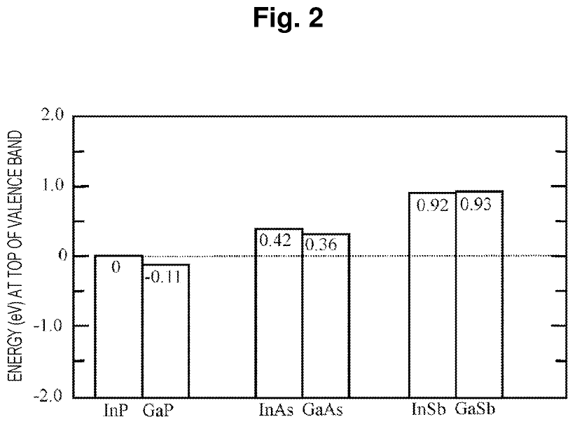

FIG. 2 is a diagram illustrating the relative positions of energy at the top of the valence band at the Γ point with respect to InP for binary mixed crystals containing P, As, and Sb as group V elements, based on the results illustrated in Reference Literature 1. As illustrated in FIG. 2, it can be seen that the energy positions at the top of the valence band are substantially equal when the contained group V elements are the same regardless of whether the contained group III elements are In or Ga.

On the other hand, the energy positions at the top greatly change depending on the contained group V elements (P, As, and Sb), and become higher in the order of (crystal containing P)<(crystal containing As)<(crystal containing Sb). From this, it can be seen that in a case of a group III-V semiconductor mixed crystal containing In and Ga as group III elements, the energy at the top of the valence band can be increased by adding Sb as a group V element.

That is, by using a material containing Sb for the barrier layer, it is possible to solve the problem caused by band discontinuity of the valence band in the InGaAsP material system described above. Specifically, in a quantum well structure using InAsP for the well layer, band discontinuity between the well layer and the barrier layer can be reduced by changing the barrier layer from InGaAsP to a composition containing Sb.

In InGaAsP, if only the group V composition ratio is simply changed to InGaAsPSb, the lattice constant increases, but the lattice constant can be reduced by increasing a molar composition ratio of Ga in the group III composition. Furthermore, since the band gap of InGaAsPSb increases by increasing the molar composition ratio of Ga in the group III composition, a decrease in band discontinuity of the conduction band can also be suppressed.

However, at present, a method for calculating the band arrangement of InGaAsPSb, which is a quinary mixed crystal, has not been established, and it is difficult to quantitatively discuss it. On the other hand, InGaAsPSb can also be regarded as a mixed crystal of InGaAsP and InGaPSb which is a quaternary mixed crystal.

As can be seen from FIG. 2, an important matter in increasing the energy positions at the top of the valence band of the barrier layer is the molar composition ratio of Sb rather than the molar composition ratio of As. Thus, when it is desired to increase the energy positions in the valence band of InGaAsPSb, it is important to consider the band arrangement of the valence band of InGaPSb rather than InGaAsP. That is, if the energy positions at the top of the valence band can be increased by InGaPSb, the energy positions can be similarly increased even when InGaAsPSb is used.

In summary, InGaAsPSb can be regarded as a mixed crystal of InGaAsP and InGaPSb, and thus can also be applied to a case where InGaAsPSb is used for the barrier layer as long as the band arrangement in a case where InGaPSb is used as the barrier layer is examined. Since InGaPSb is a quaternary mixed crystal, this band arrangement can be calculated.

Next, the band arrangement of the quantum well structure using InGaPSb for the barrier layer and InAsP for the well layer will be described.

Changes in band discontinuity of the quantum well structure in a case where InAsP is used for the well layer and the material constituting the barrier layer is changed from InGaAsP to InGaPSb were examined. The strain amount of the barrier layer was set to −0.6% for the both, InGaAsP was set to have a band gap wavelength of 1.0 μm, and InGaPSb was set to have an Sb composition ratio of 0.1 and a band gap wavelength of 1.02 μm.

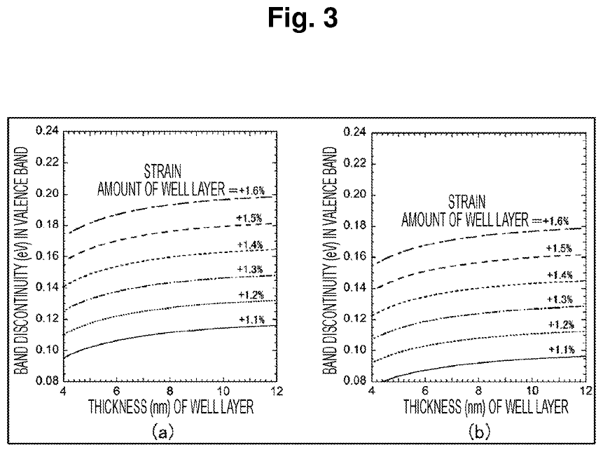

FIG. 3 illustrates a change in band discontinuity in the valence band of the quantum well structure depending on the strain amount of the well layer constituted of InAsP and the thickness of the well layer. (a) of FIG. 3 illustrates a result in a case where InGaAsP is used for the barrier layer. Further, (b) of FIG. 3 illustrates a result in a case where InGaPSb is used for the barrier layer.

The band discontinuity of the valence band has smaller energy by about 20 meV when InGaPSb is used for the barrier layer than when InGaAsP is used for the barrier layer, regardless of the strain amount and thickness of the well layer. Thus, when an electric field in an opposite direction is applied to the quantum well structure, by changing the material constituting the barrier layer from InGaAsP to InGaPSb, it becomes easy to cause the holes to move from the quantum well structure at high speed. If the holes do not remain, the influence of an internal electric field is also reduced, and thus it is also easy for the electrons to move.

That is, in the optical modulator using the quantum well structure in which the well layer is constituted of InAsP and the barrier layer is constituted of InGaPSb, carriers generated by photoexcitation can move from the quantum well structure at high speed, and consequently, on and off can be switched at high speed.

As described above, in order to give a large extinction ratio to the optical modulator using the quantum well structure, it is necessary to improve confinement of electrons in the well layer. For this purpose, it is necessary to increase the band discontinuity in the conduction band.

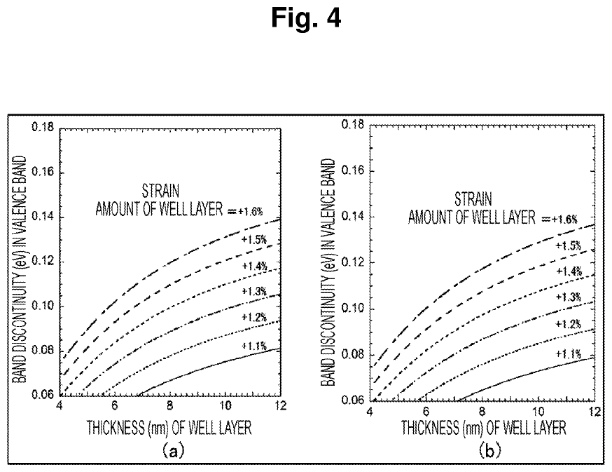

(a) of FIG. 4 illustrates a change in the band discontinuity in the conduction band depending on the strain amount of the well layer with InAsP and the thickness of the well layer with respect to a structure using InGaAs for the barrier layer described in (a) of FIG. 3. Further, (b) of FIG. 4 illustrates a change in the band discontinuity in the conduction band depending on the strain amount of the well layer with InAsP and the thickness of the well layer with respect to a structure using InGaPSb for the barrier layer described in (b) of FIG. 3.

Even when the material constituting the barrier layer is changed from InGaAsP to InGaPSb, the band discontinuity in the conduction band hardly changes. Therefore, it can be seen that even when InGaPSb is used for the barrier layer, there is no significant influence on the band discontinuity in the conduction band.

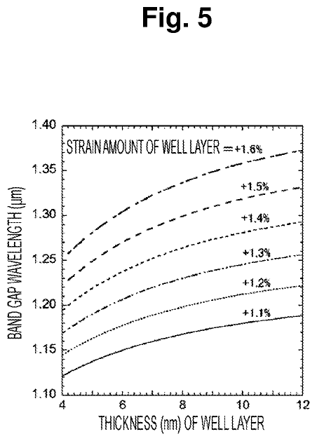

FIG. 5 illustrates a change in the band gap wavelength depending on the strain amount of the well layer and the thickness of the well layer for the quantum well structure in which the well layer is constituted of InAsP and the barrier layer is constituted of InGaPSb described with reference to (b) of FIG. 3 and (b) of FIG. 4. The band gap wavelength can be set within the wavelength range of 1.19 μm to 1.32 μm, which is useful in the optical modulator corresponding to the wavelength light around 1.3 μm described above.

In (b) of FIG. 3, (b) of FIG. 4, and FIG. 5, an example in which the strain amount is −0.6%, the Sb composition ratio is 0.1, and the band gap wavelength is 1.02 −m is illustrated as the barrier layer constituted of InGaPSb, but the strain amount, the Sb composition ratio, and the band gap wavelength of this barrier layer are not limited to these values.

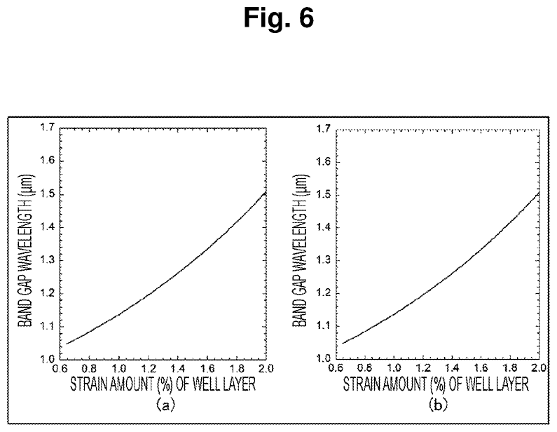

FIG. 6 is a characteristic diagram illustrating a change in the band gap wavelength in an active layer of the multiple quantum well structure depending on the strain amount of the well layer. (a) of FIG. 6 illustrates a case where a strain amount of InGaPSb constituting the barrier layer is −0.4%, the Sb composition ratio is 0.08, and the band gap wavelength is 1.0 μm. Further, (b) of FIG. 6 illustrates a case where a strain amount of InGaPSb constituting the barrier layer is −1.0%, the Sb composition ratio is 0.11, and the band gap wavelength is 1.0 μm. In both cases, the thickness of the well layer is 8 nm. As illustrated in FIG. 6, even when the barrier layer is constituted of InGaPSb, the band gap wavelength can be set within the wavelength range of 1.19 μm to 1.32 μm.

As illustrated in FIG. 2, in InGaAsP, the energy positions at the top of the valence band increase only by changing the molar composition ratio of As and Sb without changing the molar composition ratio of In, Ga, and P. Thus, when the Sb molar composition ratio of InGaAsPSb or InGaPSb is larger than 0, it is effective in reducing band discontinuity of the valence band. Thus, there is no limitation other than that the lower limit of the Sb molar composition ratio is larger than 0.

On the other hand, when production is considered, the upper limit of the Sb molar composition ratio is limited. In a mixed crystal semiconductor containing three or more elements, it is known that there is a composition region called a miscibility gap in which it is difficult to obtain a uniform composition depending on the molar composition ratio and the growth temperature of each element. This mobility gap varies greatly depending on the contained elements. It is known that InGaPSb has a larger mobility gap than InGaAsP and InGaAsSb (see, for example, Reference Literature 2).

Specifically, in a case where InGaPSb is crystal-grown on an InP substrate, when an attempt is made to grow a composition in which the Sb molar composition ratio exceeds 0.2, the influence of the mobility gap increases. Thus, when InGaPSb or InGaAsPSb that can be regarded as a mixed crystal of InGaPSb and InGaAsP is used for the barrier layer of the quantum well structure, the Sb molar composition ratio is desirably equal to or less than 0.2.

Next, an example of the present invention will be described, and a mode thereof will be described with reference to the drawings that conform to the example. First, regarding the quantum well structure used for the semiconductor element according to the present invention, for the quantum well structure using InAsP for the well layer and InGaAsSb for the barrier layer, it will be described that it is easy to increase the number of well layers by the strain compensation structure, and that light absorption by excitons, which is important for operating as the optical modulator, can be obtained.

Next, the number of well layers in the multiple quantum well structure constituting the active layer of the optical modulator according to the embodiment will be described. When the length of the optical modulator increases, the capacitance increases, so that it is difficult to cause the optical modulator to operate at high speed. For this reason, the length of the optical modulator is often shorter than the resonator length of the laser, and is generally set to about 100 to 300 μm. In order to sufficiently absorb light from a laser in this short optical modulator, it is necessary to increase the number of well layers in the quantum well structure.

However, when the number of well layers of the quantum well structure used in the optical modulator is too large, it is difficult to apply an electric field to the quantum well structure even if a bias voltage is increased. For this reason, the number of well layers of the quantum well structure used in the optical modulator needs to be determined in consideration of the thicknesses of the well layer and the barrier layer, and is often set to 6 to 20.

The quantum well structure of the active layer of the optical modulator according to the embodiment includes the well layer and the barrier layer having a relatively large strain amount, and thus there is a possibility that crystal defects caused by lattice relaxation occur. Accordingly, first, it will be described that the active layer of the optical modulator according to the embodiment has a structure capable of coping with an increase in the number of well layers.

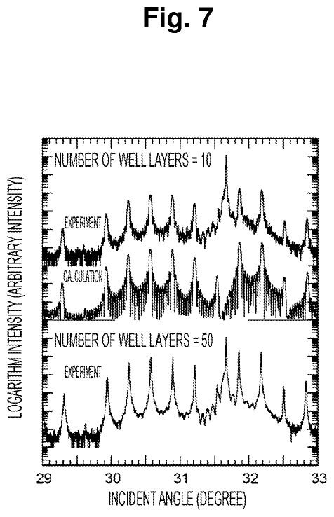

In the production of the optical modulator according to the above-described embodiment, three samples in which the number of well layers of the multiple quantum well structure constituting the active layer is 10, 30, and 50 are produced and used. FIG. 7 illustrates X-ray diffraction patterns of the sample in which the number of well layers is 10 and the sample in which the number of well layers is 50. Regarding the structure in which the number of well layers is 10, an X-ray diffraction pattern obtained by calculation is illustrated. In the calculation, only X-ray diffraction from the multiple quantum well structure (active layer) was obtained by excluding X-ray diffraction from InP with an incident angle of about 31.7 degrees.

When the X-ray diffraction from InP is excluded, the results of the experiment and the calculation are in good agreement. In FIG. 7, when peak positions of the sample in which the number of well layers is 10 and the sample in which the number of well layers is 50 are compared, both peak positions are located at substantially the same incident angle. This means that even if the number of well layers is increased, crystal defects due to lattice relaxation are less likely to occur in this quantum well structure.

Furthermore, since the intensity of each peak is almost consistent between the experiment and the calculation, it can be seen that the structure as designed is prepared. It is known that a strain compensation structure may be difficult to produce depending on a combination of materials of a compressive strain well layer and a tensile strain barrier layer (see, for example, Reference Literature 3). From the results illustrated in FIG. 7, it is considered that the combination of the materials of compressive strain InAsP as the well layer and tensile strain InGaPSb as the barrier layer is a combination in which the strain compensation structure is easily produced.

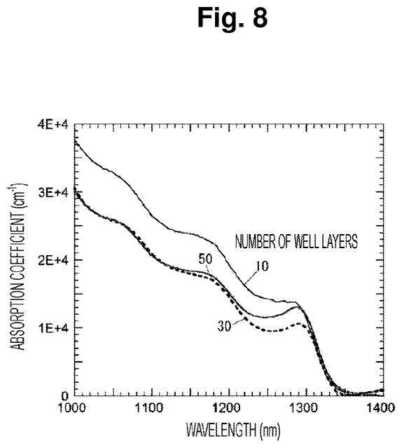

FIG. 8 illustrates absorption spectra for respective samples in which the number of well layers is 10, 30, and 50. The absorption spectrum was obtained by allowing light to enter from the sample surface and measuring a change in the intensity of transmitted light. In the absorption spectra of the sample in which the number of well layers is 30 and the sample in which the number of well layers is 50, a small bulge around a wavelength of 1.3 μm is due to light absorption by excitons.

On the other hand, in the sample in which the number of well layers is 10, light absorption by excitons is unclear. This is because light is incident from the sample surface, and specifically, since the total thickness of the well layer is only about 60 nm, it is difficult to obtain sufficient light absorption only by the well layer. When the quantum well structure is used for the optical modulator, in general, light is made incident from a side surface of the quantum well structure and propagated through the quantum well structure by about 100 to 300 μm. In this case, even in the sample in which the number of well layers is 10, the optical path length is longer than that in a case where light is surface-incident on the sample in which the number of well layers is 30 or 50, so that light absorption is increased, and consequently, it is possible to cause clear light absorption by excitons.

As described above, the quantum well structure in which InAsP is used for the well layer and InGaPSb is used for the barrier layer has a large compressive strain of the well layer, but generation of crystal defects can be suppressed even if the number of well layers is increased, and light absorption by excitons can also be used, so that it can be seen that the quantum well structure is useful as the quantum well structure used for the optical modulator.

In the above example, the case where only In, As, and P are included as elements constituting the well layer has been described, but it goes without saying that similar effects can be obtained even if Ga, Sb, or the like is included in the well layer as long as there is no significant change in the strain amount and the band arrangement.

Further, in the above example, the case where only In, Ga, P, and Sb are contained as elements constituting the barrier layer has been described, but even if the barrier layer contains As, Al, and the like besides them, it is possible to adjust the strain amount and the band arrangement depending on the composition, and thus it goes without saying that similar effects can be obtained.

Next, an application example of the optical modulator including the active layer by the multiple quantum well structure in which the well layer is constituted of InAsP and the barrier layer is constituted of InGaAsPSb will be described.

As described above, the optical modulator using a semiconductor is often integrated with a laser. A light source in which a DFB laser having an oscillation wavelength of 1.3 μm is integrated with the optical modulator according to the embodiment will be described.

First, the laser will be described. The laser includes a substrate constituted of n-type InP, a buffer layer constituted of n-type InP formed on the substrate, and a lower light confinement layer constituted of InGaAsP formed on the buffer layer. The lower light confinement layer has a composition in which a band gap wavelength is 1.05 μm.

Further, the active layer having the multiple quantum well structure is formed on the lower light confinement layer. The active layer includes a well layer constituted of InAsP and a barrier layer constituted of InGaAsP. The well layer has a layer thickness of 5.5 nm, and the barrier layer has a layer thickness of 10 nm. Further, the well layer has a strain amount of +1.5%, and the barrier layer has a strain amount of +0.5%. Furthermore, the band gap wavelength of the active layer of the multiple quantum well structure is 1.3 μm.

Further, an upper light confinement layer constituted of InGaAsP is formed on the active layer, and a cap layer constituted of p-type InP is formed on the upper light confinement layer. The upper light confinement layer has a composition in which a band gap wavelength is 1.05 μm. The lower light confinement layer and the upper light confinement layer form a separate confined heterostructure (SCH).

Each of the semiconductor layers can be formed by epitaxial growth by a metal organic molecular beam epitaxy method.

After the above-described laser structure is formed, a region to be operated as a laser is masked with a mask layer made of an insulator, and other regions are removed using a known etching method. Note that the layer structure to be operated as the optical modulator is produced by selective growth using a metal organic vapor phase epitaxy method in a state where the mask layer placed on the region to be the laser is left.

After the mask layer and the cap layer are removed in the region to be a laser unit, a

diffraction grating is formed using a known etching method. A cladding layer constituted of p-type InP and a p-type contact layer containing p-type InGaAs are grown on the substrate subjected to the above processing using the metal organic vapor phase epitaxy method. On this substrate, a ridge type waveguide structure having a mesa width of 2 μm is formed on the region used as the laser and the optical modulator by using a known etching method.

Both sides of the mesa are filled with an insulating film made of benzo cyclo butene (BCB), an ohmic electrode is formed in a patterned region on the contact layer using a known metal vapor deposition method and annealing method, and metal is vapor-deposited on a region to be a pad electrode. Note that a region (with a length in the waveguide direction: 50 μm) on which no metal is deposited is provided between the laser and the optical modulator. Cleaving is performed so that the length of the laser unit is 450 μm and the length of the optical modulator is 200 μm, and finally a wiring is connected to the electrodes to complete the light source.

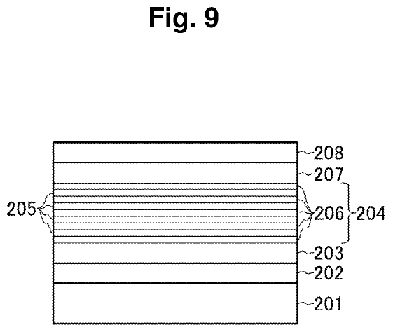

The portion of the optical modulator produced as described above will be described with reference to FIG. 9. In this optical modulator, on a substrate 201 with n-type InP in which a laser structure is formed in another region which is not illustrated, first, a first semiconductor layer 202 constituted of n-type InP and a second semiconductor layer 203 constituted of InGaAsP having a band gap wavelength of 0.98 μm and having a thickness of 50 nm are formed.

Further, the active layer 204 is formed on the second semiconductor layer 203. The active layer 204 has a multiple quantum well structure by a well layer 205 constituted of InAsP and a barrier layer 206 constituted of InGaAsPSb. The well layer 205 has a strain amount of +1.25% and a thickness of 10 nm. Further, the barrier layer 206 has a band gap wavelength of 1.03 μm, a strain amount of −0.9%, and a thickness of 7.5 nm. The band gap wavelength of the active layer 204 is 1.25 μm.

Further, on the active layer 204, a third semiconductor layer 207 constituted of InGaAsP having a band gap wavelength of 0.98 μm and having a thickness of 50 nm and a fourth semiconductor layer 208 constituted of n-type InP are formed.

For comparison with the sample of the light source described above, a comparative sample is prepared in which the barrier layer of the multiple quantum well structure constituting the active layer in the optical modulator is changed from InGaAsPSb to InGaAsP. The band gap wavelength, the strain amount, and the thickness of the barrier layer in this comparative sample are the same as the conditions of the sample.

In each of the prepared sample and the comparative sample, the laser is brought into an oscillation state, and a voltage applied to the optical modulator is changed, so that light from the laser is turned on and off in the optical modulator to generate an optical signal. Specifically, a modulation amplitude bias of 25 Gbit/s is applied to the optical modulator, and the DC bias is turned on and off to generate an optical signal. An optical signal from this light source is incident on a single mode fiber and transmitted for 40 km, and then an optical modulation waveform (eye waveform) is evaluated.

In a comparative sample using a barrier layer constituted of InGaAsP for the quantum well structure to be the optical modulator, it is difficult to obtain a clear eye opening because an eye waveform (eye pattern) is distorted. On the other hand, the sample using the barrier layer constituted of InGaAsPSb has a clearer eye opening than the comparative sample. When the eye opening becomes clear, the code error rate of the optical signal decreases. Thus, when the light source having the sample configuration is used for optical fiber communication, degradation of the optical signal is reduced, and consequently, it is possible to cope with an increase in communication speed.

In the above example, the barrier layer of the quantum well structure to be the optical modulator is constituted of InGaAsPSb, but it goes without saying that similar effects can be obtained even when the barrier layer constituted of InGaPSb is used.

Further, in the above example, since the structure to be the optical modulator is produced by regrowth after the structure to be the laser is grown, it is necessary to use the metal organic vapor phase epitaxy method or the metal organic molecular beam epitaxy method, which is a growth method suitable for selective growth, for the growth of the structure to be the optical modulator. On the other hand, the structure to be the optical modulator can be grown earlier than the structure to be the laser. In this case, not only the metal organic vapor phase epitaxy method or the metal organic molecular beam epitaxy method but also molecular beam epitaxy, gas source molecular beam epitaxy, or the like, which is a growth method in which selective growth is relatively difficult, can be used for the growth of the structure to be the optical modulator.

As described above, according to the present invention, since the barrier layer is constituted of the group III-V compound semiconductor containing In, Ga, P, and Sb as constituent elements, it is possible to cause the optical modulator to operate at high speed by applying the quantum well structure using the well layer with InAsP to the optical modulator in which the thickness of the well layer is 6 nm or more.

As described above, the quantum well structure using the well layer with InAsP is useful in a case of being applied to the optical modulator in which the thickness of the well layer is smaller than 6 nm, but in the prior art, there has been a problem that it is difficult to cause the optical modulator to operate at high speed caused by band discontinuity of the valence band in a case of being applied to the optical modulator in which the thickness of the well layer is equal to or more than 6 nm. According to embodiments of the present invention, this problem is solved, and it is possible to cause the optical modulator to operate at high speed.

According to embodiments of the present invention, it is easy to manufacture a light source having an oscillation wavelength around 1.3 μm, which has a large extinction ratio, can turn on and off an optical signal at high speed, and has high long-term reliability. Consequently, an effect of facilitating construction of an optical communication network corresponding to a rapid increase in traffic of a metro network or an access network can be expected.

Note that the present invention is not limited to the embodiment described above, and it is obvious that many modifications and combinations can be made by a person having ordinary knowledge in the art within the technical idea of the present invention.

### REFERENCE LITERATURES

Reference Literature 1—S. H. Wei et al., “Calculated natural band offsets of all II-VI and III-V semiconductors: Chemical trends and the role of cation d orbitals”, Applied Physics Letters, vol. 72, no. 16, pp. 2011-2013, 1998.
Reference Literature 2—C. Grasse et al., “Growth of various antimony-containing alloys by MOVPE”, Journal of Crystal Growth, vol. 310, pp. 4835-4838, 2008.
Reference Literature 3—M. Mitsuhara, Y. Ohiso, H. Matsuzaki, “Strain-compensated InGaAsSb/InGaAsSb multiquantum-well structure grown on InP (0 0 1) substrate as optical absorber for wavelengths beyond 2 μm”, Journal of Crystal Growth, vol. 535, 125551, 2020.

### REFERENCE SIGNS LIST

101 Substrate
102 Lower InP layer
103 Active layer
104 Well layer
105 Barrier layer
106 Upper InP layer.

1-5. (canceled)

6. An optical modulator, comprising:
an active layer having a multiple quantum well structure comprising:
a well layer constituted of a first group III-V compound semiconductor, the first group III-V compound semiconductor comprising In, As, and P; and
a barrier layer constituted of a second group III-V compound semiconductor, the second group III-V compound semiconductor comprising group III-V compound semiconductor including In, Ga, P, and Sb,
wherein a wavelength corresponding to a band gap of the multiple quantum well structure is in a range of 1.19 μm to 1.32 μm, and
wherein the optical modulator is disposed on an InP substrate.

7. The optical modulator according to claim 6, wherein:
a strain amount of the well layer is in a range of +1.1% to +1.6%.

8. The optical modulator according to claim 7, wherein:
a thickness of the well layer is equal to or more than 6 nm and equal to or less than 12 nm.

9. The optical modulator according to claim 8, wherein:
the active layer comprises a plurality of the well layers, and a quantity of the plurality of well layers is between 6 and 20.

10. The optical modulator according to claim 7, wherein:
the well layer is constituted of InAsP, and
the barrier layer is constituted of InGaPSb or InGaAsPSb.

11. The optical modulator according to claim 7, wherein:
the optical modulator is integrated together with a laser on the InP substrate.

12. The optical modulator according to claim 6, wherein:
a molar composition ratio of Sb in group V elements of the barrier layer is larger than o and equal to or less than 0.2.

13. The optical modulator according to claim 6, wherein:
the well layer is constituted of InAsP, and
the barrier layer is constituted of InGaPSb or InGaAsPSb.

14. The optical modulator according to claim 6, wherein
the optical modulator is integrated together with a laser on the InP substrate.

15. A method of forming an optical modulator, the method comprising:
forming an active layer having a multiple quantum well structure on an InP substrate, the multiple quantum well structure comprising:
a well layer constituted of a first group III-V compound semiconductor, the first group III-V compound semiconductor comprising In, As, and P; and
a barrier layer constituted of a second group III-V compound semiconductor, the second group III-V compound semiconductor comprising group III-V compound semiconductor including In, Ga, P, and Sb, wherein a wavelength corresponding to a band gap of the multiple quantum well structure is in a range of 1.19 μm to 1.32 μm.

16. The method according to claim 15, wherein:
a strain amount of the well layer is in a range of +1.1% to +1.6%.

17. The method according to claim 16, wherein:
a thickness of the well layer is equal to or more than 6 nm and equal to or less than 12 nm.

18. The method according to claim 17, wherein:
the active layer comprises a plurality of the well layers, and a quantity of the plurality of well layers is between 6 and 20.

19. The method according to claim 16, wherein:
the well layer is constituted of InAsP, and
the barrier layer is constituted of InGaPSb or InGaAsPSb.

20. The method according to claim 16, wherein:
the optical modulator is integrated together with a laser on the InP substrate.

21. The method according to claim 15, wherein:
a molar composition ratio of Sb in group V elements of the barrier layer is larger than 0 and equal to or less than 0.2.

22. The method according to claim 15, wherein:
the well layer is constituted of InAsP, and
the barrier layer is constituted of InGaPSb or InGaAsPSb.

23. The method according to claim 15, wherein:
the optical modulator is integrated together with a laser on the InP substrate.
